(19) United States
(12) Patent Application Publication
(10) Pub. No.: US 2005/0002167 A1
(43) Pub. Date: Jan. 6, 2005

(54) Microelectronic package

(76) Inventors: John Hsuan, Hsin-Chu City (TW); Kuo-Ming Chen, Hsin Chu Hsien (TW); Kow-Bao Chen, Hsin-Chu City (TW); Hung-Min Liu, Hsin-Chu City (TW); Kai-Kuang Ho, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 10/610,638

(22) Filed: Jul. 2, 2003

(51) Int. Cl. H05K 7/06

(52) U.S. Cl. 361/760; 361/782; 361/761; 257/724

(57) ABSTRACT

An improved microelectronic package is disclosed. The microelectronic package includes a packaging substrate having an upper surface and an underside. At least one chip is mounted on the upper surface of the packaging substrate. A plurality of ball grid array (BGA) solder balls are mounted at the underside of the packaging substrate. At least one RC passive component is disposed underneath the chip. The chip may be mounted on predetermined position on the upper surface of the packaging substrate with solder bumps by using Flip-Chip (FC) assembly method. According to one aspect of the present invention, the RC passive component is disposed between the BGA solder balls. According to one aspect of the present invention, the RC passive component is an adjustable resist having a plurality of bumps formed thereon, and wherein two metal trace lines, which correspond to two bumps of the plural bumps, are provided on the underside of the packaging substrate. The distance between the two metal trace lines determines the resistance value of the adjustable resist.

### BACKGROUND OF THE INVENTION

1. Field of the Invention

The present invention relates generally to a microelectronic package. More specifically, a ball grid array (BGA) semiconductor package, which encompasses an RC passive component mounted underneath a chip or die thereof, is disclosed for saving substrate area and improving electric performance.

2. Description of the Prior Art

With the increasing need for high-density devices for use in lightweight, portable electronics, there has been a gradual shift in the sizes of integrated circuits and their package configurations. This gradual shift has resulted in developing various techniques for different package types. Typically, for semiconductor packages having the lead count above 300 leads, a ball grid array (BGA) package is utilized. The BGA package utilizes tape or other adhesive materials to adhere a back surface of a chip onto a substrate. A plurality of bonding pads are electrically connected to a plurality of nodes of the substrate by conductive wires. A molding compound encapsulates the chip, conductive wires and nodes. A plurality of solder balls are formed on the nodes of the substrate. The above-mentioned structure of a BGA package can utilize solder balls to electrically connect to external circuits. BGA is noted for its compact size, high lead count and low inductance, which allows lower voltages to be used. BGA chips are easier to align to the printed circuit board, because the balls are farther apart than leaded packages. Since the balls are underneath the chip, BGA has led the way to chip scale packaging (CSP) where the package is not more than 1.2 times the size of the semiconductor die itself.

In accomplishment with desirable electricity and functionality, it tends to incorporate passive components such as capacitor, resistor, or inductor in a semiconductor package.

Please refer to FIG. 1. FIG. 1 is a schematic, cross-sectional view illustrating a prior art semiconductor package 1. As shown in FIG. 1, the prior art semiconductor package 1 comprises a packaging substrate 10 having an upper surface (or active surface) 2 and an underside 3. As known to those skilled in the art, the packaging substrate 10 may be a multi-chip module (MCM) substrate, on which multiple chips can be installed and packaged together. A chip 101 and a chip 102 are aligned on respective predetermined positions of the upper surface 2 of the packaging substrate 10. For example, the chip 101 and a chip 102 are mounted on the packaging substrate 10 with solder bumps 12 by using a known Flip-Chip (FC) assembly method. Gaps between the chips and the packaging substrate 10 are then filled with resin materials called underfill 13, which is used to release the stress on the solder bumps 12. The prior art semiconductor package 1 further comprises an RC passive component 11 such as a resist or a capacitor. The RC passive component 11 is mounted on the peripheral area of the upper surface 2 of the packaging substrate 10 using surface mounting technique (SMT). An array of BGA solder balls 14 is provided on the underside 3 of the packaging substrate 10. Through the BGA solder balls 14, the semiconductor package 1 can be electrically connected to a printed circuit board (not shown).

However, the above-mentioned prior art semiconductor package 1 has several drawbacks. First, the RC passive component 11 of the prior art semiconductor package 1 is disposed at the same side as the chips 101 and 102, thus occupies an excess substrate area and therefore increases product cost. Secondly, although the prior art semiconductor package 1 has a relatively small BGA package size, the RC passive component 11 disposed on the upper surface of the packaging substrate 10 is still distant from the chips 101 and 102, and such long conductive path leads to poor electric performance.

In light of the foregoing, there is a need to provide an improved chip package structure that is capable of eliminating the aforementioned problems.

### SUMMARY OF INVENTION

Accordingly, the primary object of the present invention is to provide an improved microelectronic package structure having RC passive components disposed underneath corresponding IC chips or die, thereby minimizing the conductive path between the IC chips and the passive components.

Another object of the present invention is to provide a microelectronic package structure having an IC chip and an RC passive component disposed on opposite sides of a packaging substrate, thereby shrinking needed substrate area and production cost.

Still another object of the present invention is to provide an improved BGA semiconductor package having an RC passive component disposed on the underside of a packaging substrate between BGA solder balls, thereby shrinking package size, needed substrate area and production cost.

To achieve these and other advantages and in accordance with the purposes of the invention, as embodied and broadly described herein, the present invention provides A microelectronic package, comprising a packaging substrate comprising an upper surface and an underside; at least one chip mounted on the upper surface of the packaging substrate; a plurality of ball grid array (BGA) solder balls mounted at the underside of the packaging substrate; and at least one RC passive component disposed underneath the chip. The chip may be mounted on predetermined position on the upper surface of the packaging substrate with solder bumps by using Flip-Chip (FC) assembly method. According to one aspect of the present invention, the RC passive component is disposed between the BGA solder balls. According to one aspect of the present invention, the RC passive component is an adjustable resist having a plurality of bumps formed thereon, and wherein two metal trace lines, which correspond to two bumps of the plural bumps, are provided on the underside of the packaging substrate. The distance between the two metal trace lines determines the resistance value of the adjustable resist.

Other objects, advantages, and novel features of the claimed invention will become more clearly and readily apparent from the following detailed description when taken in conjunction with the accompanying drawings.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a schematic, cross-sectional view illustrating a prior art semiconductor package;

FIG. 2 is a schematic, cross-sectional diagram illustrating a flip-chip BGA package in accordance with the first preferred embodiment of the present invention;

FIG. 3 is a bottom plan view of the flip-chip BGA package as set forth in FIG. 2;

FIG. 4 is a bottom (underside 6) plan view of the flip-chip BGA package 4 as set forth in FIG. 2 in accordance with the second preferred embodiment of the present invention;

FIG. 5 depicts the cross-section of a wire-bonding package in accordance with the third preferred embodiment of the present invention;

FIG. 6 is a schematic, cross-sectional diagram illustrating a flip-chip BGA package in accordance with the fourth preferred embodiment of the present invention;

FIG. 7 is a schematic, cross-sectional diagram illustrating a flip-chip BGA package in accordance with the fifth preferred embodiment of the present invention;

FIG. 8 is a schematic, cross-sectional diagram illustrating a flip-chip BGA package in accordance with the sixth preferred embodiment of the present invention; and

FIG. 9 and FIG. 10 schematically illustrate a general-type adjustable RC passive component and corresponding substrate configuration in accordance with the present invention.

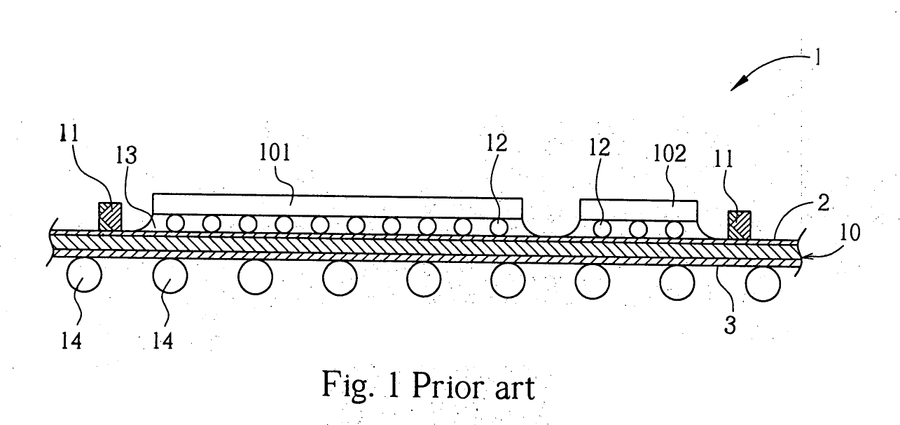

### DETAILED DESCRIPTION

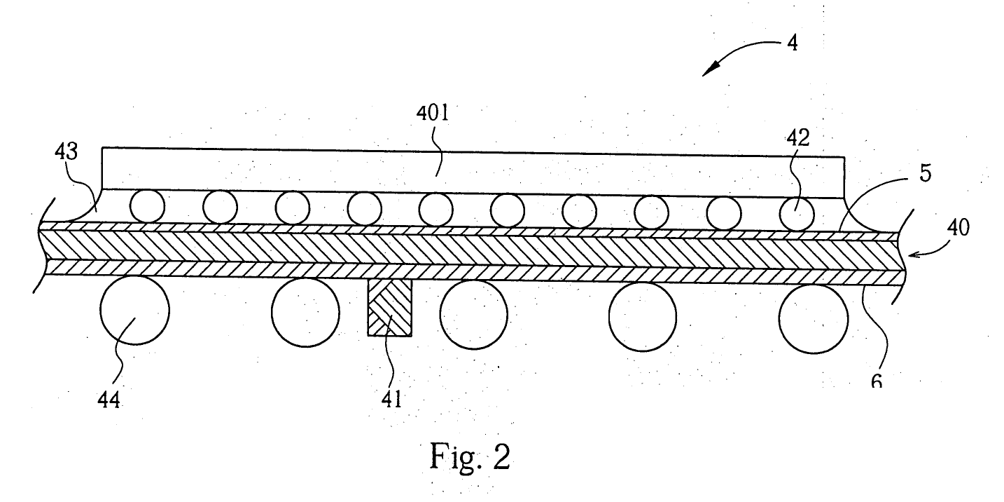

Please refer to FIG. 2. FIG. 2 is a schematic, cross-sectional diagram illustrating a flip-chip BGA package 4 in accordance with the first preferred embodiment of the present invention. As shown in FIG. 2, the flip-chip BGA package 4 comprises a packaging substrate 40 having an upper surface (or active surface) 5 and an underside 6. The packaging substrate 40 may be a multi-level substrate or a multi-chip module (MCM) substrate. Generally, the packaging substrate 40 is made of polymers having high glass transformation temperature (Tg) such as FR-4.8, FR-5, bismaleimide-triazine (BT) resin, Driclad, or Hitachi 679 F, but not limited thereto. By way of example, the packaging substrate 40 is a two-layer substrate having two metal wiring layers printed on respective upper surface 5 and the underside 6 of the packaging substrate 40, and a plurality of vias in the packaging substrate 40 for electrically connecting the two metal wiring layers. The chip 401 is mounted on the predetermined position such as solder bump pads provided on the upper surface 5 of the packaging substrate 40 with solder bumps 42 by using a known Flip-Chip (FC) assembly method. Optionally, the gap between the chip 401 and the packaging substrate 40 is then filled with underfill materials 43, which is used to release the stress on the solder bumps 42. It is appreciated that the underfill materials may be fluid type or non-fluid type. In some cases, the underfill is omitted.

The flip-chip BGA package 4 further comprises an RC passive component 41 such as a resist or a capacitor, which is mounted on the underside 6 of the packaging substrate 40 by using known surface mounting technique (SMT). Preferably, the RC passive component 41 is disposed underneath the chip 401 to minimize the conductive path between the chip 401 and the RC passive component 41. After the SMT process of the RC passive component 41, an array of BGA solder balls 44 is formed on the underside 6 of the packaging substrate 40. Through the BGA solder balls 44, the flip-chip BGA package 4 can be electrically connected to a printed circuit board (not shown).

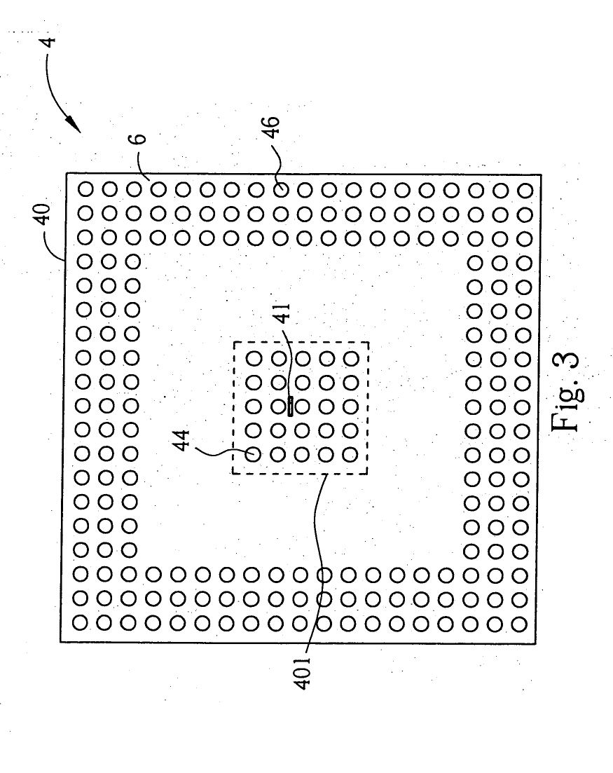

Please refer to FIG. 3. FIG. 3 is a bottom (underside 6) plan view of the flip-chip BGA package 4 as set forth in FIG. 2. In accordance with the first preferred embodiment of the present invention, an array of dummy solder balls (or heat-dissipating solder balls) 44 is disposed at the central area of the underside 6 of the packaging substrate 40 for heat dissipation. In use, heat generated by the chip 401 will be dissipated to the underlying printed circuit board (PCB) through the array of dummy solder balls 44. The communication between the PCB and the IC chip 401 is conducted through area solder balls 46. As specifically indicated, the RC passive component 41 such as resist, capacitor, or the like, is mounted between dummy solder balls 44 on the underside 6 of the packaging substrate 40 by using SMT.

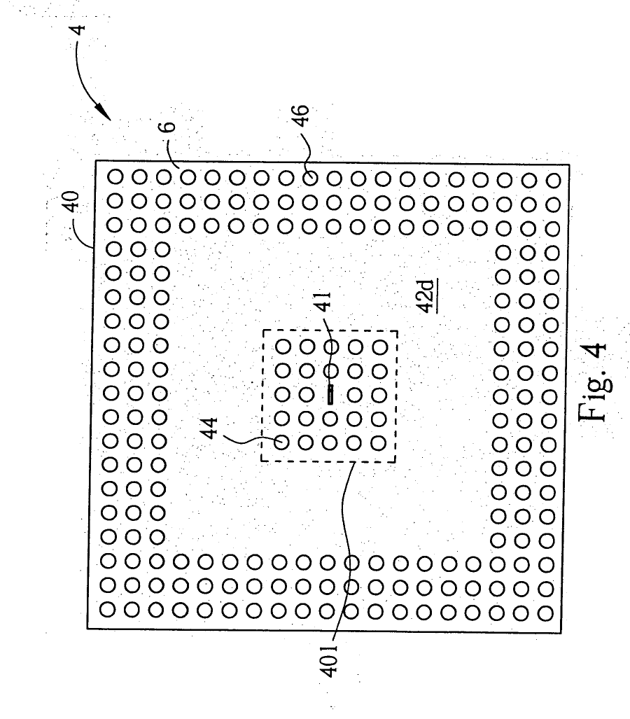

Please refer to FIG. 4. FIG. 4 is a bottom (underside 6) plan view of the flip-chip BGA package 4 as set forth in FIG. 2 in accordance with the second preferred embodiment of the present invention. Likewise, an array of dummy solder balls (or heat-dissipating solder balls) 44 is disposed at the central area of the underside 6 of the packaging substrate 40 for heat dissipation. In use, heat generated by the chip 401 will be dissipated to the underlying PCB through the array of dummy solder balls 44. The communication between the PCB and the IC chip 401 is conducted through area solder balls 46. The difference between FIG. 3 (first embodiment) and FIG. 4 (second embodiment) is that one or two dummy solder balls are cancelled from the solder ball array, and the RC passive component 41 is mounted at the position where the dummy solder balls are cancelled, as shown in FIG. 4. The RC passive component 41 is mounted between dummy solder balls 44 on the underside 6 of the packaging substrate 40 by using SMT.

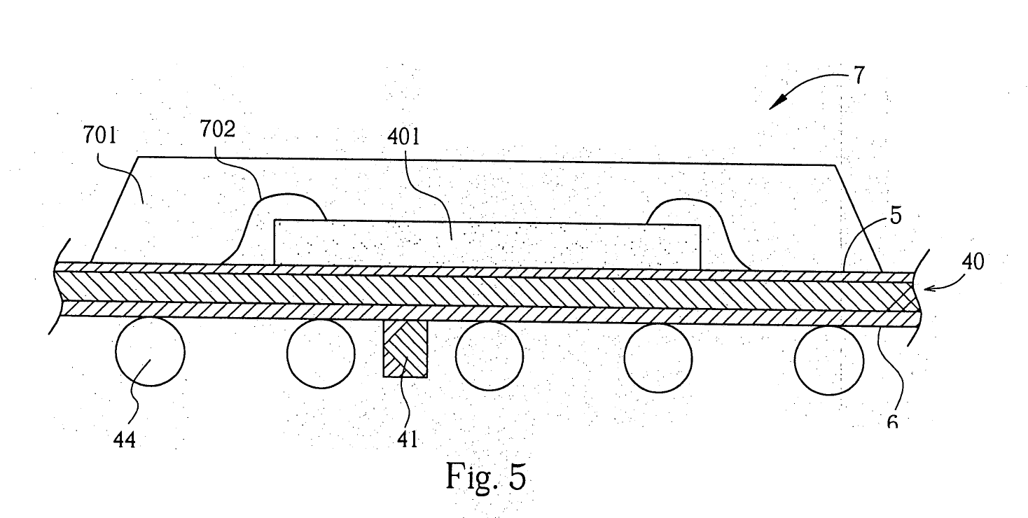

It is also advantageous to apply the present invention to conventional wire bonding package in addition to flip-chip BGA package. Please refer to FIG. 5. FIG. 5 depicts the cross-section of a wire-bonding package 7 in accordance with the third preferred embodiment of the present invention. As shown in FIG. 5, the wire-bonding package 7 comprises a packaging substrate 40 having an upper surface (or active surface) 5 and an underside 6. The packaging substrate 40 may be a multi-level substrate or a multi-chip module (MCM) substrate. Generally, the packaging substrate 40 is made of polymers having high glass transformation temperature (Tg) such as FR-4.8, FR-5, bismaleimide-triazine (BT) resin, Driclad, or Hitachi 679F, but not limited thereto. By way of example, the packaging substrate 40 is a two-layer substrate having two metal wiring layers printed on respective upper surface 5 and the underside 6 of the packaging substrate 40, and a plurality of vias in the packaging substrate 40 for electrically connecting the two metal wiring layers. The chip 401 is mounted on the predetermined position on the upper surface 5 of the packaging substrate 40 by SMT. A plurality of gold wires 702 are provided to connect the chip 401 and corresponding connecting pads (not shown) on the packaging substrate 40. The chip 401 and the gold wires 702 are then enclosed by insulation resin 701.

The wire-bonding package 7 further comprises an RC passive component 41 such as a resist or a capacitor, which is mounted on the underside 6 of the packaging substrate 40 by SMT. Preferably, the RC passive component 41 is disposed underneath the chip 401 to minimize the conductive path between the chip 401 and the RC passive component 41. After the SMT process of the RC passive component 41, an array of BGA solder balls 44 is formed on the underside 6 of the packaging substrate 40. Through the BGA solder balls 44, the flip-chip BGA package 4 can be electrically connected to a printed circuit board (not shown).

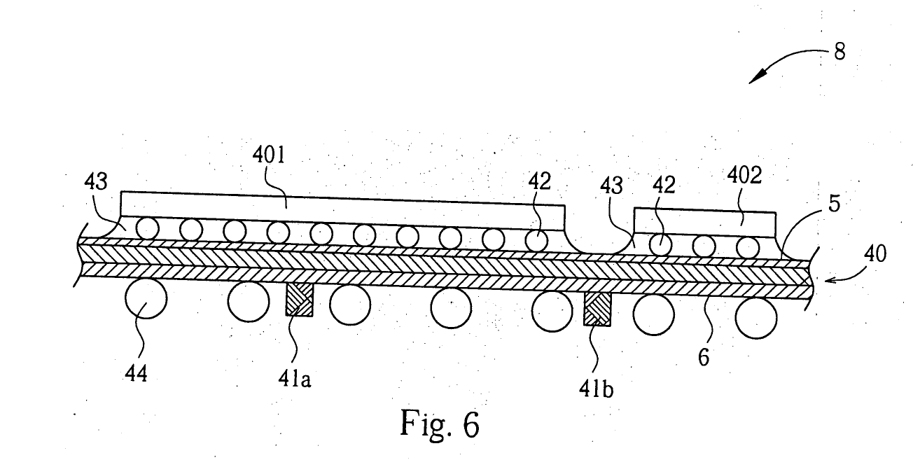

Please refer to FIG. 6. FIG. 6 is a schematic, cross-sectional diagram illustrating a flip-chip BGA package 8 in accordance with the fourth preferred embodiment of the present invention. As shown in FIG. 6, the flip-chip BGA package 8 comprises a packaging substrate 40 having an upper surface 5 and an underside 6. The packaging substrate 40 is a multi-chip module (MCM) substrate. Chip 401 and chip 402 are mounted on the predetermined positions such as solder bump pads provided on the upper surface 5 of the packaging substrate 40 with solder bumps 42 by using a known Flip-Chip (FC) assembly method. The gaps between the chip 401 and 402 and the packaging substrate 40 is then filled with underfill materials 43, which is used to release the stress on the solder bumps 42. It is appreciated that the underfill materials may be fluid type or non-fluid type. In some cases, the underfill is omitted.

The flip-chip BGA package 8 further comprises an RC passive components 41a and 41b such as a resist or a capacitor, which are mounted on the underside 6 of the packaging substrate 40 by SMT. Preferably, the RC passive components 41a and 41b are disposed underneath the chips 401 and 402, respectively, to minimize the conductive path between the chip 401 and the RC passive components 41a and 41b. After the SMT process of the RC passive components 41a and 41b, an array of BGA solder balls 44 is formed on the underside 6 of the packaging substrate 40. Through the BGA solder balls 44, the flip-chip BGA package 4 can be electrically connected to a printed circuit board (not shown).

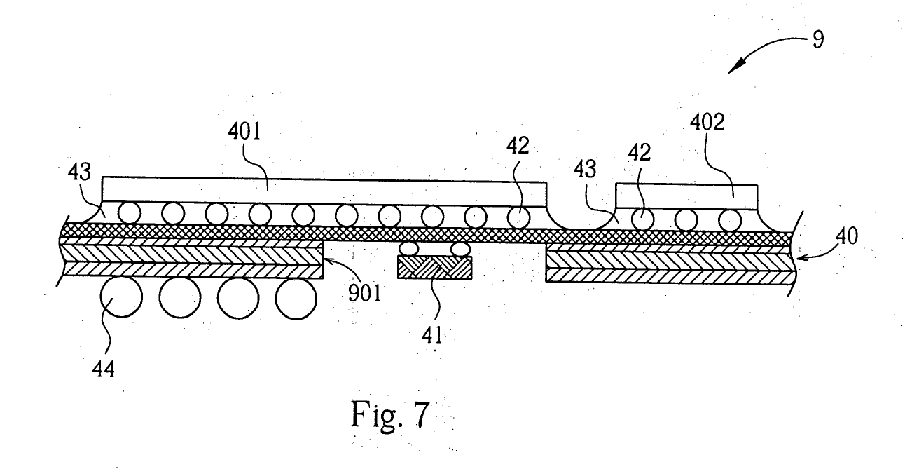

Please refer to FIG. 7. FIG. 7 is a schematic, cross-sectional diagram illustrating a flip-chip BGA package 9 in accordance with the fifth preferred embodiment of the present invention. As shown in FIG. 7, the flip-chip BGA package 9 comprises a packaging substrate 40 having an upper surface 5 and an underside 6. The packaging substrate 40 is a MCM substrate. A recess 901 is provided at the underside 6 of the packaging substrate 40 and is located underneath the chip 401. Chip 401 and chip 402 are mounted on the predetermined positions of the upper surface 5 of the packaging substrate 40 with solder bumps 42 by FC assembly method. The gaps between the chip 401 and 402 and the packaging substrate 40 is then filled with underfill materials 43, which is used to release the stress on the solder bumps 42. It is appreciated that the underfill materials may be fluid type or non-fluid type. In some cases, the underfill is omitted.

The flip-chip BGA package 9 further comprises an RC passive component 41 such as a resist or a capacitor, which are mounted within the recess 901 at the underside 6 of the packaging substrate 40 by SMT. Preferably, the RC passive component 41 is disposed underneath the chip 401 to minimize the conductive path between the chip 401 and the RC passive component 41. After the SMT process of the RC passive component 41, an array of BGA solder balls 44 is formed on the underside 6 of the packaging substrate 40.

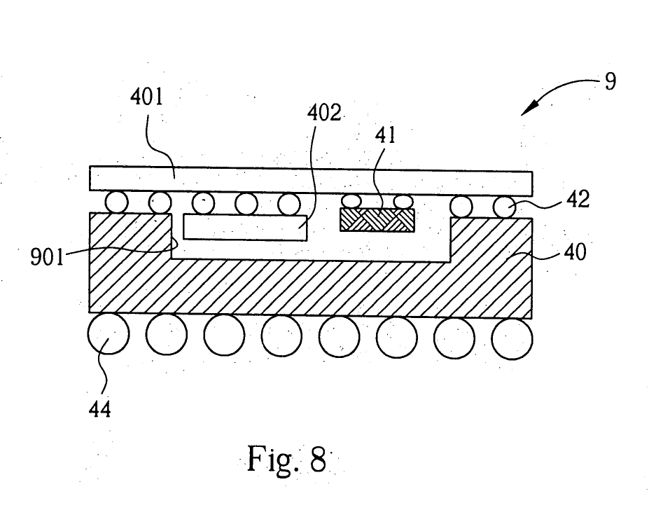

Please refer to FIG. 8. FIG. 8 is a schematic, cross-sectional diagram illustrating a flip-chip BGA package 91 in accordance with the sixth preferred embodiment of the present invention. As shown in FIG. 8, the flip-chip BGA package 91 comprises a packaging substrate 40 having an upper surface 5 and an underside 6. The packaging substrate 40 is a MCM substrate. A recess 901 is provided at the upper surface 5 of the packaging substrate 40. The flip-chip BGA package 91 further comprises chips 401 and 402, and RC passive component 41, wherein the RC passive component 41 such as a resist or a capacitor is mounted on the bottom of the chip 402 by SMT. The resultant combination of the chip 402 and the RC passive component 41 is accommodated in the recess 901. The chip 401 is mounted on the predetermined position of the upper surface 5 of the packaging substrate 40 with solder bumps 42 by FC assembly method. Optionally, the gap between the chip 401 and the packaging substrate 40 is then filled with underfill materials 43, which is used to release the stress on the solder bumps 42. It is appreciated that the underfill materials may be fluid type or non-fluid type. In some cases, the underfill is omitted. An array of BGA solder balls 44 is formed on the underside 6 of the packaging substrate 40. Through the BGA solder balls 44, the flip-chip BGA package 91 can be electrically connected to a printed circuit board (not shown).

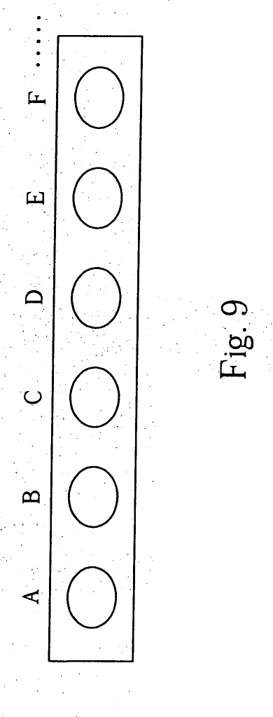

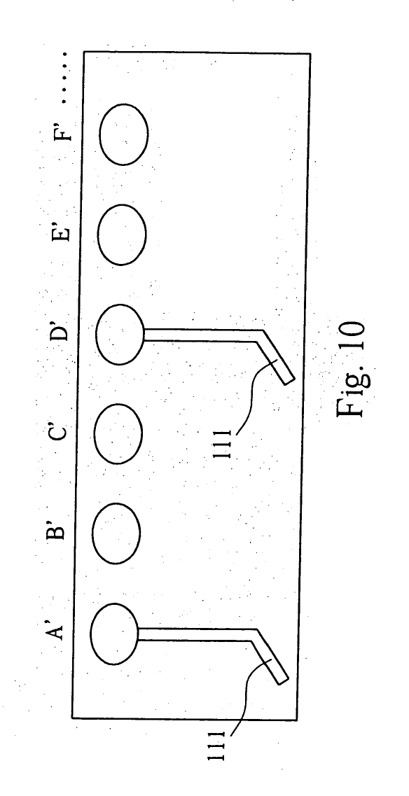

Please refer to FIG. 9 and FIG. 10. FIG. 9 and FIG. 10 schematically illustrate a general-type adjustable RC passive component and corresponding substrate configuration in accordance with the present invention. As shown in FIG. 9, a general-type adjustable RC passive component such as an adjustable resist or an adjustable capacitor is provided. It is understood that the practical resistance range of the general-type adjustable RC passive component is designed to cover applications as broad as possible. As indicated in FIG. 9, wafer-level bumps A˜F, for example, are formed on an RC passive component. After wafer sawing, the RC passive component with bumps is stored in a state awaiting the following SMT process. As shown in FIG. 10, connecting pads A′˜F′ corresponding to bumps A˜F on the general-type adjustable RC passive component are provided on a chip or on a packaging substrate. After the desired resistance value or capacitance value is decided, metal trace lines 111 are formed to connect respective two connecting pads. After the formation of the metal trace lines 111, the general-type adjustable RC passive component is mounted on the metal trace lines 111 by FC assembly and SMT process.

To sum up, one major characteristic of this invention is that the RC passive components such as resists or capacitors are disposed underneath the chip(s) which is mounted on an active surface of a BGA packaging substrate. The RC passive component can be disposed between solder balls or replace the position of dummy solder balls arranged in a heat-dissipating solder ball array which is located at the underside of the BGA packaging substrate. In another case, the RC passive component can be surface-mounted within a cavity or recess provided at the underside of the BGA packaging substrate. As a result, the substrate area is reduced and the electric performance is improved because the conductive path between the RC passive component and the chip is minimized. Another characteristic of this invention is that the RC passive component may be a general-type adjustable resist or capacitor. Metal trace lines formed on the chip or substrate, which connected to corresponding connecting pads, determine the desired resistance value or capacitance value. Moreover, the present invention structure is totally compatible with conventional Flip-Chip assembly and SMT processes.

Those skilled in the art will readily observe that numerous modifications and alterations of the present invention may be made while retaining the teachings of the invention. Accordingly, the above disclosure should be construed as limited only by the metes and bounds of the appended claims.

1. A microelectronic package, comprising:
a packaging substrate comprising an upper surface and an underside;
at least one chip mounted on the upper surface of the packaging substrate;
a plurality of ball grid array (BGA) solder balls mounted at the underside of the packaging substrate; and
at least one RC passive component disposed at the underside of the packaging substrate.

2. The microelectronic package as claimed in claim 1 wherein the chip is mounted on predetermined position on the upper surface of the packaging substrate with solder bumps by using Flip-Chip (FC) assembly method.

3. The microelectronic package as claimed in claim 1 wherein the chip is mounted on the upper surface of the packaging substrate by surface mounting technique (SMT) and is electrically connected with the packaging substrate by wire bonding.

4. The microelectronic package as claimed in claim 1 wherein the RC passive component is disposed between the BGA solder balls.

5. The microelectronic package as claimed in claim 1 wherein the RC passive component is located underneath the chip.

6. The microelectronic package as claimed in claim 1 wherein the packaging substrate is a two-layer substrate having two metal wiring layers printed on respective upper surface and the underside of the packaging substrate, and a plurality of vias in the packaging substrate for electrically connecting the two metal wiring layers.

7. The microelectronic package as claimed in claim 1 wherein the RC passive component is an adjustable resist having a plurality of bumps formed thereon, and wherein two metal trace lines, which correspond to two bumps of the plural bumps, are provided on the underside of the packaging substrate, and wherein the distance between the two metal trace lines determines the resistance value of the adjustable resist.

8. The microelectronic package as claimed in claim 1 wherein the packaging substrate further comprises a recess provided at the underside, and the RC passive component is located within the recess.

9. The microelectronic package as claimed in claim 8 wherein the recess comprises a bottom surface and the RC passive component is mounted on the bottom surface of the recess by SMT.

10. A microelectronic package, comprising:
a packaging substrate comprising an upper surface and an underside;
at least one chip mounted on the upper surface of the packaging substrate;
a plurality of ball grid array (BGA) solder balls mounted at the underside of the packaging substrate; and
at least one RC passive component disposed underneath the chip.

11. The microelectronic package as claimed in claim 10 wherein the packaging substrate further comprises a recess provided on the upper surface, and wherein the chip and the RC passive component are disposed within the recess.

12. The microelectronic package as claimed in claim 11 wherein the RC passive component is mounted on a bottom of the chip by surface mounting technique (SMT).

13. The microelectronic package as claimed in claim 10 wherein the chip is mounted on predetermined position on the upper surface of the packaging substrate with solder bumps by using Flip-Chip (FC) assembly method.

14. The microelectronic package as claimed in claim 10 wherein the chip is mounted on the upper surface of the packaging substrate by SMT and is electrically connected with the packaging substrate by wire bonding.

15. The microelectronic package as claimed in claim 10 wherein the RC passive component is mounted on the underside of the packaging substrate.

16. The microelectronic package as claimed in claim 10 wherein the RC passive component is disposed between the BGA solder balls.

17. The microelectronic package as claimed in claim 10 wherein the packaging substrate is a two-layer substrate having two metal wiring layers printed on respective upper surface and the underside of the packaging substrate, and a plurality of vias in the packaging substrate for electrically connecting the two metal wiring layers.

18. The microelectronic package as claimed in claim 10 wherein the RC passive component is an adjustable resist having a plurality of bumps formed thereon, and wherein two metal trace lines, which correspond to two bumps of the plural bumps, are provided on the underside of the packaging substrate, and wherein the distance between the two metal trace lines determines the resistance value of the adjustable resist.

19. The microelectronic package as claimed in claim 10 wherein the packaging substrate further comprises a recess provided at the underside, and the RC passive component is located within the recess.

20. The microelectronic package as claimed in claim 19 wherein the recess comprises a bottom surface and the RC passive component is mounted on the bottom surface of the recess by SMT.
